(19) United States
(12) Patent Application Publication
(10) Pub. No.: US 2019/0386039 A1
(43) Pub. Date: Dec. 19, 2019

(54) ARRAY SUBSTRATE AND DISPLAY APPARATUS

(71) Applicant: WUHAN CHINA STAR OPTOELECTRONICS TECHNOLOGY CO., LTD., Wuhan, HB (CN)

(72) Inventor: Yuebai Han, Shenzhen (CN)

(73) Assignee: WUHAN CHINA STAR OPTOELECTRONICS TECHNOLOGY CO., LTD., Wuhan, HB (CN)

(21) Appl. No.: 15/740,980

(22) PCT Filed: Oct. 20, 2017
(86) PCT No.: PCT/CN2017/107146

§ 371 Date: Aug. 29, 2018

(30) Foreign Application Priority Data
Jul. 25, 2017 (CN) 201710612912.8

(51) Int. Cl. H01L 27/12

(52) U.S. Cl. CPC H01L 27/1244

(57) ABSTRACT

The present disclosure relates to the field of display technologies, and discloses an array substrate and a display apparatus. The array substrate includes a base layer, pixel circuits and signal lines. The pixel circuits are disposed on the base layer in an array form, the signal lines are disposed on the base layer in a row direction or a column direction and coupled to the pixel circuits, and at least one of the signal lines is disposed at an outermost side of the pixel circuits disposed in the array form and at least one of the other signal lines that is disposed in a same direction with the signal line is disposed at the opposite outermost side of the pixel circuits disposed in the array form.

### TECHNICAL FIELD

The present disclosure relates to the field of display technologies, and particularly, to an array substrate and a display apparatus.

### BACKGROUND

The present applicant has, by chance, found the following technical problem that had not ever been found in the prior art: because of the complex manufacturing process of low-temperature polysilicon devices, electro-static discharge (ESD) is more likely to occur during the manufacturing process of low-temperature polysilicon display panels. As a consequence, a large amount of charges accumulate to cause exploded damage of gates and the polysilicon layer at edges of the panel. This results in short-circuit between the gates and the polysilicon layer, thus introducing the gate signal into the polysilicon layer to cause poor electrical performance.

FIG. 1 shows a schematic structural view of an array substrate 100 in the prior art. The array substrate 100 comprises a base layer 10 (only a portion thereof being shown), a polysilicon layer 11 (i.e., the inverted-U shaped layer in the drawing) located over the base layer 10, a gate line layer 12 located over the polysilicon layer 11, a data line layer 13 located over the gate line layer 12, via holes 14 for connecting the polysilicon layer 11 and the data line layer 13, and breakline symbols 15 that indicate repeated extension in the respective direction. The aforesaid term “located over . . . ” is only used to describe relative positional relationships, and does not necessarily means a close touch. For unlabeled parts in FIG. 1, the reference symbols and meanings thereof are just the same as corresponding parts at the top left corner of FIG. 1.

The present applicant has found that the structure of the array substrate 100 shown in FIG. 1 tends to cause exploded damage of the gates and the polysilicon layer at edges of the panel. That is, exploded damage is caused at locations 16 where vertical projections of the gate lines and a vertical projection of the polysilicon layer overlap with each other, and this results in short-circuit between the gates and the polysilicon layer, thus introducing the gate signal into the polysilicon layer to cause poor electrical performance.

Orientations (e.g., the rightmost side, the topmost side, the bottommost side or the like of the display panel) set forth with respect to the array substrate or the display panel in this specification are only used to indicate relative orientation relationships; and in terms of this specification, the specific orientations are defined on the basis that the display panel is disposed at a typical orientation in use. For example, the side closer to the viewer is called “top” while the side farther from the viewer is called “bottom”.

### SUMMARY

The present disclosure provides an array substrate and a display apparatus, which are intended to solve the problem of poor electrical performance caused by electro-static discharge during the manufacturing process of display panels.

A first aspect of embodiments of the present disclosure provides an array substrate, including: a base layer; pixel circuits, disposed on the base layer in an array form; signal lines, disposed on the base layer in a row direction or a column direction and coupled to the pixel circuits; wherein at least two of the signal lines that are disposed in a same direction are disposed at opposite outermost sides of the pixel circuits disposed in the array form; the signal lines include first data lines that are disposed in the column direction and a second data line that is disposed in the column direction; the second data line is located at a rightmost side of the array substrate, a corresponding one of the pixel circuits coupled to the second data line is located at a left side of the second data line; and all other signal lines arranged in the column direction than the second data line are the first data lines, and each of the first data lines is located at a left side of a corresponding one of the pixel circuits that is coupled thereto; the signal lines include first gate lines that are disposed in the row direction and a second gate line that is disposed in the row direction; the second gate line is located at a bottommost side of the array substrate, a corresponding one of the pixel circuits that is coupled to the second gate line is located at a top side of the second gate line; and all other signal lines arranged in the column direction than the second gate line are the first gate lines, and each of the first gate lines is located at a top side of a corresponding one of the pixel circuits that is coupled thereto.

A second aspect of the embodiments of the present disclosure provides an array substrate, including: a base layer; pixel circuits, disposed on the base layer in an array form; signal lines, disposed on the base layer in a row direction or a column direction and coupled to the pixel circuits; wherein at least two of the signal lines that are disposed in a same direction are disposed at opposite outermost sides of the pixel circuits disposed in the array form.

A third aspect of the embodiments of the present disclosure provides a display apparatus, including: a base layer; pixel circuits, disposed on the base layer in an array form; signal lines, disposed on the base layer in a row direction or a column direction and coupled to the pixel circuits; wherein at least two of the signal lines that are disposed in a same direction are disposed at opposite outermost sides of the pixel circuits disposed in the array form.

As compared to the prior art, the technical solutions provided in the present disclosure have the following benefits: in the prior art design, the pixel circuits on the panel are entirely of an array structure and the electro-static discharge tends to cause short-circuit between the gate lines and the polysilicon layer due to exploded damage thereof to result in poor electrical performance; in contrast, the embodiments of the present disclosure dispose at least two signal lines disposed in a same direction at opposite outermost sides of the pixel circuits arranged in the array form respectively, and this allows the electro-static charges at at least two ends of the display panel to be dissipated out through the signal lines, thus effectively reducing the probability of poor electrical performance and improving the product yield.

### BRIEF DESCRIPTION OF THE DRAWINGS

FIG. 1 is a schematic structural view of an array substrate provided in the prior art;

FIG. 2 is a schematic structural view of an array substrate provided in a first embodiment of the present disclosure;

FIG. 3 is a schematic structural view of another array substrate provided in the first embodiment of the present disclosure;

FIG. 4 is a partial cross-sectional view of the another array substrate provided in the first embodiment of the present disclosure along a vertical signal line extending direction;

FIG. 5 is a schematic structural view of another array substrate provided in the first embodiment of the present disclosure;

FIG. 6 is a schematic structural view of another array substrate provided in the first embodiment of the present disclosure;

FIG. 7 is a schematic view of a display apparatus provided in a first embodiment of the present disclosure.

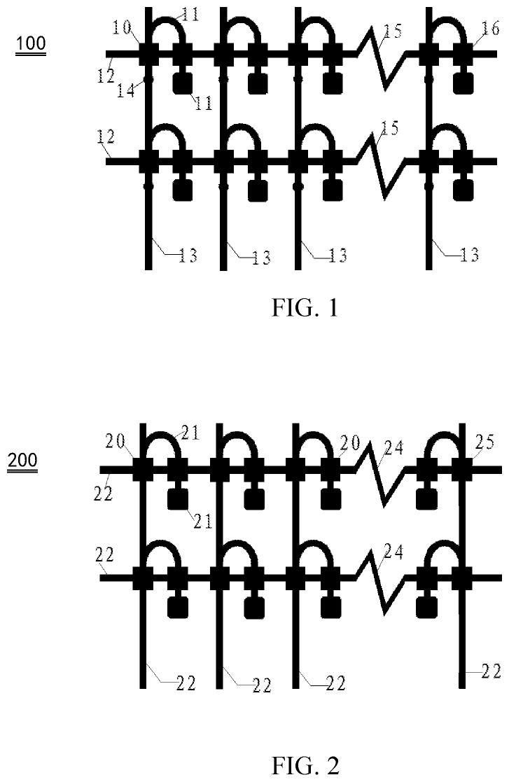

### DETAILED DESCRIPTION

To make the objectives, technical solutions and advantages of the present disclosure more clear, the present disclosure will be further detailed hereinbelow with reference to the attached drawings and embodiments thereof.

In the following description, for purpose of illustration rather than limitation, schematic views illustrating technical features are provided to aid in thorough understanding of the embodiments of the present disclosure. However, those skilled in the art shall be appreciated that, the present disclosure can be implemented in other embodiments without these details. In other cases, detailed description of well-known structures is omitted to avoid obscuring the present disclosure by unnecessary details.

A first embodiment of the present disclosure provides an array substrate, which includes: a base layer; pixel circuits, disposed on the base layer in an array form; signal lines, disposed on the base layer in a row direction or a column direction and coupled to the pixel circuits; wherein at least one of the signal lines is disposed at an outermost side of the pixel circuits of the array form, and at least another of the signal lines in a same direction is disposed at an opposite outermost side of the pixel circuits of the array form. Hereinbelow, the array substrate will be detailed with reference to texts and the illustrative attached drawings.

Referring to FIG. 2, there is shown a schematic structural view of an array substrate 200 provided in the first embodiment of the present disclosure. For convenience of description, FIG. 2 only shows portions related to the first embodiment of the present disclosure. As shown in FIG. 2, the array substrate 200 includes a base layer, pixel circuits 21 and signal lines 22. The pixel circuits 21 are disposed on the base layer in an array form, the signal lines 22 are disposed on the base layer in a row direction or a column direction and coupled to the pixel circuits 21, wherein at least one of the signal lines 22 is disposed at an outermost side of the pixel circuits 21 of the array form, and at least another of the signal lines 22 in a same direction is disposed at an opposite outermost side of the pixel circuits 21 of the array form. FIG. 2 is only of an illustrative nature, and uses breakline symbols 24 that indicate repeated extensions in the respective direction.

Optionally, the base layer is at the bottom of a light shielding layer 20 indicated by black blocks at locations where vertical projections of the signal lines 22 are overlapped in FIG. 2.

It shall be noted that, a plan view is selected in FIG. 2 to express the inventive concepts of this application, and for convenience of expression and for compliance with regulations on the attached drawings (black lines shall be adopted), the base layer is not shown. According to the orientation relationships defined in this application, the base layer is generally located below all circuit construction layers.

Optionally, the base layer may be located under the pixel circuits 21 and the signal lines 22 shown in FIG. 2.

Optionally, the pixel circuits 21 may include a polysilicon layer, i.e., the portion indicated by the black block at an end of each inverted-U shape in FIG. 2. The pixel circuits 21 shown in FIG. 2 may be the polysilicon layer.

Optionally, the signal lines 22 may include gate lines and data lines. In FIG. 2, the horizontally arranged signal lines 22 may be the gate lines and the vertically arranged signal lines 22 may be the data lines.

Optionally, the signal lines 22 being disposed on the base layer in a row direction or a column direction may mean that the signal lines 22 are in close touch with the base layer, or the signal lines 22 are located above the base layer without touching the base layer.

Optionally, the signal lines 22 being coupled to the pixel circuits 21 may mean that a corresponding one of the vertically arranged signal lines 22 is coupled to the polysilicon layer of a corresponding one of the pixel circuits 21.

It shall be appreciated that, although the above description is only a simple description, it can be clearly understood and defined by those skilled in the art with reference to the prior art.

Optionally, at portions where vertical projections of the vertical signal lines 22, the horizontal signal lines 22, the pixel circuits 21 the light shielding layer 20 and the base layer are overlapped with each other, these layers are arranged in the following order from bottom to top: the base layer, the light shielding layer 20, the pixel circuits layer 21, the horizontal signal lines 22, and the vertical signal lines 22.

Optionally, the at least two signal lines 22 described in “at least two of the signal lines 22 that are disposed in a same direction are disposed at opposite outermost sides of the pixel circuits 21 disposed in the array form” may be the leftmost vertically arranged signal line 22 and the rightmost vertically arranged signal line 22 illustrated in FIG. 2.

It shall be noted that, for convenience of description, parts unlabeled in FIG. 2 have the same reference symbols and meanings as corresponding parts at the top left corner of FIG. 2.

It shall be noted that, disposing at least one of the signal lines 22 at an outermost side of the pixel circuits 21 of the array form, and at least another of the signal lines 22 in a same direction at the opposite outermost side of the pixel circuits 21 of the array form can allow accumulated charges or charges from the outside to be quickly dissipated out through the leftmost vertically arranged signal line 22 and the rightmost vertically arranged signal line 22 illustrated in FIG. 2, thus effectively avoiding exploded damage of the horizontal signal lines 22 and the pixel circuit layer 21 at locations 25 where their vertical projections are overlapped. This can effectively reduce the probability of poor electrical performance and improve the product yield.

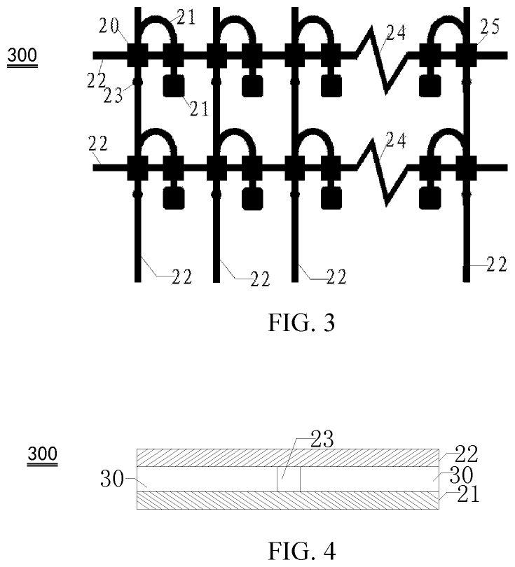

FIG. 3 is a schematic structural view of another array substrate 300 provided in the first embodiment of the present disclosure. The array substrate 300 illustrated in FIG. 3 may further include via holes 23 each of which is used for connecting a corresponding one of the pixel circuits 21 and a corresponding one of the signal lines 22. The via holes 23 illustrated in FIG. 3 may connect a corresponding one of the vertical signal lines 22 and a corresponding one of the pixel circuits 21, and for parts not described in FIG. 3, the reference symbols and meanings thereof are just the same as those of FIG. 2, so they will not be further described again.

FIG. 4 is a partial cross-sectional view of the array substrate 300 provided in the first embodiment of the present disclosure along a vertical signal line extending direction. There are shown the pixel circuits 21, the vertical signal lines layer 22, a separation layer 30 interposed between the pixel circuits 21 and the vertical signal lines layer 22, and the via holes 23 for connecting the pixel circuits 21 and the vertical signal lines 22.

Optionally, a polysilicon layer included in the pixel circuits 21 may be coupled to a corresponding one of the signal lines 22 through a corresponding one of the via holes 23. What shown in FIG. 3 is that the polysilicon layer of the pixel circuits 21 is coupled to a corresponding one of the vertical signal lines 22 through a corresponding one of the via holes 23, i.e., the polysilicon layer is coupled to a corresponding one of data lines through a corresponding one of the via holes 23.

In this way, the accumulated charges can be transferred from the polysilicon layer to the data lines through the via holes 23, and then dissipated out by the data lines.

This can effectively avoid exploded damage of the horizontal signal lines 22 (which may be gate lines) and the polysilicon layer at the locations 25 where their vertical projections are overlapped with each other due to the accumulated charges, thus avoiding short-circuit between the gate lines and the polysilicon layer which would otherwise introduce the gate signal into the polysilicon to cause poor electrical performance.

Optionally, the polysilicon layer may be a low-temperature polysilicon layer.

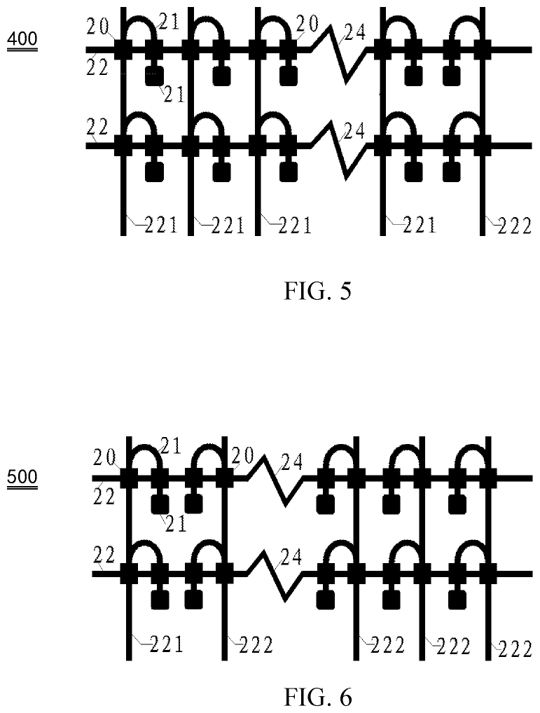

Optionally, FIG. 5 shows a schematic structural view of another array substrate 400 according to the first embodiment of the present disclosure. The signal lines 22 may include first data lines 221 which are disposed in the column direction and second data lines 222 which are disposed in the column direction, the number of the second data lines 222 is one, the second data line 222 is located at a rightmost side of the array substrate 200, a corresponding one of the pixel circuits 21 that is coupled to the second data line 222 is located at a left side of the second data line 222, all other signal lines disposed in the column direction other than the second data line 222 are the first data lines 221, and each of the first data lines 221 is located at a left side of a corresponding one of the pixel circuits 21 that is coupled thereto. For parts not described in FIG. 5, reference symbols and meanings thereof are the same as those of FIG. 2 or FIG. 3 and will not be further described again.

Optionally, there may be more than one second data line 222. For example, an arbitrary number of second data lines 222 may be inserted between the rightmost second data line 222 and the first data lines 221 in FIG. 5.

Optionally, FIG. 6 shows a schematic structural view of another array substrate 500. The signal lines 22 may include first data lines 221 which are disposed in the column direction and second data lines 222 which are disposed in the column direction, the number of the first data lines 221 is one, the first data line 221 is located at a leftmost side of the array substrate 200, a corresponding one of the pixel circuits 21 that is coupled to the first data line 221 is located at a right side of the first data line 222, all other signal lines disposed in the column direction other than the first data line 221 are the second data lines 222, and each of the second data lines 222 is located at the right side of a corresponding one of the pixel circuits 21 that is coupled thereto. For parts not described in FIG. 6, reference symbols and meanings thereof are the same as those of FIG. 2 or FIG. 3 and will not be further described again.

Optionally, there may be more than one first data line 221. For example, an arbitrary number of first data lines 221 may be inserted between the leftmost first data line 221 and the second data lines 222 in FIG. 6.

It shall be appreciated that, the array substrate 300 illustrated in FIG. 5 and the array substrate 400 illustrated in FIG. 6 above can well solve the technical problem of poor electrical performance at the rightmost side of the display panel found by the present applicant, and improve the yield of display panels.

Optionally, the signal lines 22 include first gate lines that are disposed in the row direction and second gate lines that are disposed in the row direction, the number of the second gate lines is one, the second gate line is located at a bottommost side of the array substrate 200, a corresponding one of the pixel circuits 21 that is coupled to the second gate line is located at a top side of the second gate line; and all other signal lines 22 arranged in the row direction than the second gate line are the first gate lines, and each of the first gate lines is located at a top side of a corresponding one of the pixel circuits 21 that is coupled thereto.

Optionally, there may be more than one second gate line, and the description about this is similar to the aforesaid case where there may be more than one second data line or first data line and will not be further described again.

Optionally, the signal lines 22 include first gate lines that are disposed in the row direction and second gate lines that are disposed in the row direction, the number of the first gate lines is one, the first gate line is located at a topmost side of the array substrate 200, a corresponding one of the pixel circuits 21 that is coupled to the first gate line is located at a bottom side of the second gate line; and all other signal lines 22 arranged in the row direction than the first gate line are the second gate lines, and each of the second gate lines is located at a bottom side of a corresponding one of the pixel circuits 21 that is coupled thereto.

Optionally, there may be more than one first gate line, and the description about this is similar to the aforesaid case where there may be more than one second data line or first data line or second gate line and will not be further described again.

Optionally, the description of the case where the signal lines 22 include the first gate lines arranged in the row direction and the second gate lines arranged in the row direction is similar to the description of the case where the signal lines 22 include the first data lines 221 arranged in the column direction and the second data lines 222 arranged in the column direction, and because the case where the signal lines 22 include the first gate lines arranged in the row direction and the second gate lines arranged in the row direction will be clearly understood by those skilled in the art by reviewing the description of the case where the signal lines 22 include the first data lines 221 arranged in the column direction and the second data lines 222 arranged in the column direction, it will not be further described again.

Optionally, descriptions related to FIG. 2, FIG. 3 and FIG. 4 can all apply to the aforesaid case where the signal lines 22 include the first data lines 221 arranged in the column direction and the second data lines 222 arranged in the column direction and the case where the signal lines 22 include the first gate lines arranged in the row direction and the second gate lines arranged in the row direction. For example, in the aforesaid case where the signal lines 22 include the first data lines 221 arranged in the column direction and the second data lines 222 arranged in the column direction and the case where the signal lines 22 include the first gate lines arranged in the row direction and the second gate lines arranged in the row direction, via holes for connecting the pixel circuits and the signal lines may be further included, the pixel circuits may include a polysilicon layer, the signal lines may include data lines, each of the via holes may be used for connecting the polysilicon layer of a corresponding one of the pixel circuits and a corresponding one of the data lines, the accumulated charges may be transferred from the polysilicon layer to the data lines through the via holes and then dissipated out through the data lines, and the polysilicon layer may be a low-temperature polysilicon layer.

Optionally, each of the pixel circuits 21 includes a polysilicon layer 211, and the polysilicon layer 221 is coupled to a corresponding one of the signal lines 22 through a corresponding one of the via holes 23.

In the prior art, the pixel circuits on the panel are entirely of an array structure, and such a design tends to cause short-circuit due to exploded damage of the gate lines and the polysilicon layer, thus resulting in poor electrical performance. In contrast, the embodiments of the present disclosure dispose at least a signal line at an outermost side of the pixel circuits of the array form and another of signal lines in a same direction at the opposite outermost side of the pixel circuits of the array form, and this allows the electro-static charges at at least two ends of the display panel to be dissipated out through this at least two signal lines, thus effectively reducing the probability of poor electrical performance and improving the product yield. On the other hand, the accumulated charges can be quickly dissipated out through the signal lines to significantly reduce bright spot defects at edges of the products and improve the displaying quality.

A display apparatus is provided in a second embodiment of the present disclosure, which includes: a base layer; pixel circuits, disposed on the base layer in an array form; signal lines, disposed on the base layer in a row direction or a column direction and coupled to the pixel circuits; wherein at least one of the signal lines is disposed at an outermost side of the pixel circuits of the array form, and at least another of the signal lines in a same direction is disposed at an opposite outermost side of the pixel circuits of the array form.

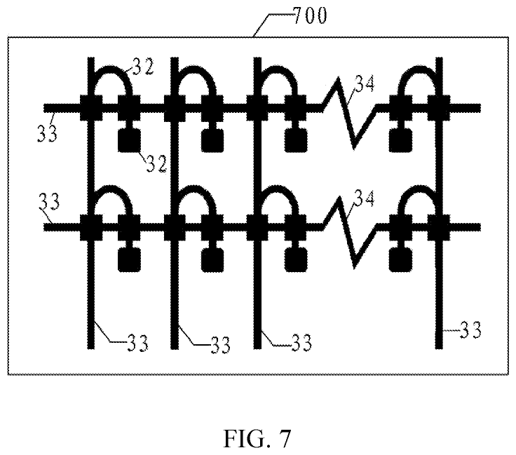

Referring to FIG. 7, which shows a schematic structural view of a display apparatus 300 provided in the second embodiment of the present disclosure. For convenience of description, FIG. 7 shows only portions related to the second embodiment of the present disclosure. The display apparatus 700 includes: a base layer 31; pixel circuits 32, disposed on the base layer 31 in an array form; signal lines 33, disposed on the base layer 31 in a row direction or a column direction and coupled to the pixel circuits 32; wherein at least one of the signal lines 33 is disposed at an outermost side of the pixel circuits 32 of the array form, and at least another of the signal lines 33 in a same direction is disposed at an opposite outermost side of the pixel circuits 32 of the array form. FIG. 7 is only of an illustrative nature, and uses breakline symbols 34 that indicate repeated extensions in the respective direction.

Optionally, the signal lines include first data lines that are disposed in the column direction and second data lines that are disposed in the column direction; the number of the second data lines is one, the second data line is located at a rightmost side of the array substrate, and a corresponding one of the pixel circuits coupled to the second data line is located at a left side of the second data line; all other signal lines arranged in the column direction than the second data line are the first data lines, and each of the first data lines is located at a left side of a corresponding one of the pixel circuits that is coupled thereto.

Optionally, the signal lines include first data lines that are disposed in the column direction and second data lines that are disposed in the column direction; the number of the first data lines is one, the first data line is located at a leftmost side of the array substrate, and a corresponding one of the pixel circuits coupled to the first data line is located at a right side of the second data line; all other signal lines arranged in the column direction than the first data line are the second data lines, and each of the second data lines is located at a right side of a corresponding one of the pixel circuits that is coupled thereto.

Optionally, the signal lines include first gate lines that are disposed in a row direction and second gate lines that are disposed in a row direction; the number of the second gate lines is one, the second gate line is located at a bottommost side of the array substrate, and a corresponding one of the pixel circuits that is coupled to the second gate line is located at a top side of the second gate line; all other signal lines arranged in the row direction than the second gate line are the first gate lines, and each of the first gate lines is located at a top side of a corresponding one of the pixel circuits that is coupled thereto.

the signal lines include first gate lines that are disposed in a row direction and second gate lines that are disposed in a row direction; the number of the first gate lines is one, the first gate line is located at a topmost side of the array substrate, and a corresponding one of the pixel circuits that is coupled to the first gate line is located at a bottom side of the first gate line; all other signal lines arranged in the row direction than the first gate line are the second gate lines, and each of the second gate lines is located at a bottom side of a corresponding one of the pixel circuits that is coupled thereto.

Optionally, each of the pixel circuits includes a polysilicon layer that is coupled to a corresponding one of the signal lines through a corresponding via hole.

Optionally, optionally, the polysilicon layer is a low-temperature polysilicon layer.

Interpretations of corresponding terms and sentences in the aforesaid array substrate embodiment can all apply to this embodiment, so they will not be further described again.

It shall be noted that, because the display apparatus embodiment is based on the same concept and delivers the same technical effect as the array substrate embodiment, reference may be made to the description of the array substrate embodiment and no detailed description will be made again.

It shall be noted that, the terms such as “first” and “second” in all the embodiments of the present disclosure, e.g., the first data lines, the second data lines and etc., are used only for convenience of expression and reference but do not mean that there are necessarily corresponding first data lines and second data lines in practical implementations of the present disclosure.

What described above are only detailed descriptions on the principles and implementations of the present disclosure that are made with reference to specific embodiments thereof, and the present disclosure shall not be considered to be limited by these descriptions; and rather, these descriptions are only used to aid in understanding of the method and key ideas of the present disclosure. Meanwhile, as apparent to those of ordinary skill in the art, any equivalent structures or equivalent process flow modifications that are made according to the specification and the attached drawings of the present disclosure, or any direct or indirect applications of the present disclosure in other related technical fields shall all be covered within the scope of the present disclosure.

1. An array substrate, comprising:
a base layer;
pixel circuits, disposed on the base layer in an array form;
signal lines, disposed on the base layer in a row direction or a column direction and coupled to the pixel circuits;
wherein at least two of the signal lines that are disposed in a same direction are disposed at opposite outermost sides of the pixel circuits;
the signal lines comprise first data lines that are disposed in the column direction and a second data line that is disposed in the column direction; the second data line is located at a rightmost side of the array substrate, a first corresponding pixel circuit coupled to the second data line is located at a left side of the second data line; and all other signal lines arranged in the column direction other than the second data line are the first data lines, and each of the first data lines is located at a left side of a corresponding pixel circuit that is coupled thereto;
the signal lines comprise first gate lines that are disposed in the row direction and a second gate line that is disposed in the row direction; the second gate line is located at a bottommost side of the array substrate, a second corresponding pixel circuit that is coupled to the second gate line is located at a top side of the second gate line; and all other signal lines arranged in the row direction other than the second gate line are the first gate lines, and each of the first gate lines is located at a top side of a corresponding pixel circuit that is coupled thereto.

2. The array substrate of claim 1, wherein,
the array substrate further comprises a plurality of light shielding layers each disposed on the base layer and under the pixel circuits and the signal lines, and each of the light shielding layers is disposed corresponding to a coupling between one of the pixel circuits and a corresponding signal line.

3. The array substrate of claim 1, wherein,
each of the pixel circuits comprises a polysilicon layer that is coupled to one of the signal lines via a corresponding hole.

4. An array substrate, comprising:
a base layer;
pixel circuits, disposed on the base layer in an array form;
signal lines, disposed on the base layer in a row direction or a column direction and coupled to the pixel circuits;
wherein at least two of the signal lines that are disposed in a same direction are disposed at opposite outermost sides of the pixel circuits.

5. The array substrate of claim 4, wherein,
the signal lines comprise first data lines that are disposed in the column direction and a second data line that is disposed in the column direction; the second data line is located at a rightmost side of the array substrate, and a first corresponding pixel circuit coupled to the second data line is located at a left side of the second data line;
all other signal lines arranged in the column direction other than the second data line are the first data lines, and each of the first data lines is located at a left side of a corresponding pixel circuit that is coupled thereto.

6. The array substrate of claim 4, wherein,
the signal lines comprise a first data line that is disposed in the column direction and second data lines that are disposed in the column direction; the first data line is located at a leftmost side of the array substrate, and a first corresponding pixel circuit coupled to the first data line is located at a right side of the first data line;
all other signal lines arranged in the column direction other than the first data line are the second data lines, and each of the second data lines is located at a right side of a corresponding one of the pixel circuits that is coupled thereto.

7. The array substrate of claim 4, wherein,
the signal lines comprise first gate lines that are disposed in the row direction and a second gate line that is disposed in the row direction; the second gate line is located at a bottommost side of the array substrate, and a second corresponding pixel circuit that is coupled to the second gate line is located at a top side of the second gate line;
all other signal lines arranged in the row direction other than the second gate line are the first gate lines, and each of the first gate lines is located at a top side of a corresponding pixel circuit that is coupled thereto.

8. The array substrate of claim 4, wherein,
the signal lines comprise a first gate line that is disposed in the row direction and second gate lines that are disposed in the row direction; the first gate line is located at a topmost side of the array substrate, and a second corresponding pixel circuit that is coupled to the first gate line is located at a bottom side of the first gate line;
all other signal lines arranged in the row direction other than the first gate line are the second gate lines, and each of the second gate lines is located at a bottom side of a corresponding pixel circuit that is coupled thereto.

9. The array substrate of claim 4, wherein,
each of the pixel circuits comprises a polysilicon layer that is coupled to one of the signal lines via a corresponding hole.

10. The array substrate of claim 4, wherein,
the array substrate further comprises a plurality of light shielding layers each disposed on the base layer and under the pixel circuits and the signal lines, and each of the light shielding layers is disposed corresponding to a coupling between one of the pixel circuits and a corresponding signal line.

11. A display apparatus, comprising:
a base layer;
pixel circuits, disposed on the base layer in an array form;
signal lines, disposed on the base layer in a row direction or a column direction and coupled to the pixel circuits;
wherein at least two of the signal lines that are disposed in a same direction are disposed at opposite outermost sides of the pixel circuits.

12. The display apparatus of claim 11, wherein,
the signal lines comprise first data lines that are disposed in the column direction and a second data line that is disposed in the column direction; the second data line is located at a rightmost side of the array substrate, and a first corresponding pixel circuit coupled to the second data line is located at a left side of the second data line;
all other signal lines arranged in the column direction other than the second data line are the first data lines, and each of the first data lines is located at a left side of a corresponding pixel circuit that is coupled thereto.

13. The display apparatus of claim 11, wherein,
the signal lines comprise a first data line that is disposed in the column direction and second data lines that are disposed in the column direction; the first data line is located at a leftmost side of the array substrate, and a first corresponding pixel circuit coupled to the first data line is located at a right side of the first data line;
all other signal lines arranged in the column direction other than the first data line are the second data lines, and each of the second data lines is located at a right side of a corresponding one of the pixel circuits that is coupled thereto.

14. The display apparatus of claim 11, wherein,
the signal lines comprise first gate lines that are disposed in the row direction and a second gate line that is disposed in the row direction; the second gate line is located at a bottommost side of the array substrate, and a second corresponding pixel circuit that is coupled to the second gate line is located at a top side of the second gate line;
all other signal lines arranged in the row direction other than the second gate line are the first gate lines, and each of the first gate lines is located at a top side of a corresponding pixel circuit that is coupled thereto.

15. The display apparatus of claim 11, wherein,
the signal lines comprise a first gate line that is disposed in the row direction and second gate lines that are disposed in the row direction; the first gate line is located at a topmost side of the array substrate, and a second corresponding pixel circuit that is coupled to the first gate line is located at a bottom side of the first gate line;
all other signal lines arranged in the row direction other than the first gate line are the second gate lines, and each of the second gate lines is located at a bottom side of a corresponding pixel circuit that is coupled thereto.

16. The display apparatus of claim 11, wherein,
each of the pixel circuits comprises a polysilicon layer that is coupled to one of the signal lines via a corresponding hole.

17. The display apparatus of claim 11, wherein,
the array substrate further comprises a plurality of light shielding layers each disposed on the base layer and under the pixel circuits and the signal lines, and each of the light shielding layers is disposed corresponding to a couplings between one of the pixel circuits and a corresponding signal line.

18. The array substrate of claim 3, wherein,
the polysilicon layer is a low-temperature polysilicon layer.

19. The array substrate of claim 9, wherein,
the polysilicon layer is a low-temperature polysilicon layer.

20. The display apparatus of claim 16, wherein,
the polysilicon layer is a low-temperature polysilicon layer.
